(19) United States
(12) Patent Application Publication
(10) Pub. No.: US 2026/0032927 A1
(43) Pub. Date: Jan. 29, 2026

(54) MICROELECTRONIC DEVICES INCLUDING CRUCIFORM CONTACT STRUCTURES, AND RELATED METHODS AND ELECTRONIC SYSTEMS

(71) Applicant: Micron Technology, Inc., Boise, ID (US)

(72) Inventors: Eric S. Carman, San Francisco, CA (US); Mingdong Cui, Folsom, CA (US); Veeresh Salimath, Folsom, CA (US)

(21) Appl. No.: 19/255,355

(22) Filed: Jun. 30, 2025

Related U.S. Application Data
(60) Provisional application No. 63/676,615, filed on Jul. 29, 2024.

(51) Int. Cl. H10B 80/00; H01L 23/00; H01L 25/00; H01L 25/065; H01L 25/18

(52) U.S. Cl. CPC H10B 80/00; H01L 24/05; H01L 24/08; H01L 24/80; H01L 25/0657; H01L 25/18; H01L 25/50; H01L 2224/05013; H01L 2224/05022; H01L 2224/08145; H01L 2224/80123; H01L 2224/80895; H01L 2224/80896; H01L 2924/1431; H01L 2924/1434

(57) ABSTRACT

A microelectronic device includes a first microelectronic device structure, a second microelectronic device structure bonded to the first microelectronic device structure, and cruciform contact structures at a bonding interface of the first microelectronic device structure and the second microelectronic device structure. The cruciform contact structures respectively include a first conductive bar and a second conductive bar bonded to the first conductive bar. The first conductive bar has a first rectangular shape, a major horizontal dimension of the first conductive bar oriented in a first direction. The second conductive bar has a second rectangular shape, a major horizontal dimension of the second conductive bar oriented in a second direction orthogonal to the first direction. Related methods and electronic systems are also described.

### CROSS-REFERENCE TO RELATED APPLICATIONS

This application claims the benefit under 35 U.S.C. § 119 (e) of U.S. Provisional Patent Application Ser. No. 63/676,615, filed Jul. 29, 2024, the disclosure of which is hereby incorporated herein in its entirety by this reference.

### TECHNICAL FIELD

The disclosure, in various embodiments, relates generally to the field of microelectronic device design and fabrication. More specifically, the disclosure relates to methods of forming a microelectronic device including bonded contact structures, and to related microelectronic devices and electronic systems.

### BACKGROUND

Microelectronic device structure designers often desire to increase the level of integration or density of features within a microelectronic device structure by reducing the dimensions of the individual features and by reducing the separation distance between neighboring features. In addition, microelectronic device structure designers often desire to design architectures that are not only compact, but offer performance advantages, as well as simplified designs.

One example of a microelectronic device structure is a memory device. Memory devices are generally provided as internal integrated circuits in computers or other electronic devices. There are many types of memory devices including, but not limited to, volatile memory devices, such as dynamic random-access memory (DRAM) devices; and non-volatile memory devices such as NAND Flash memory devices Modern applications for memory devices can employ significant quantities of memory cells, arranged in memory arrays. Memory arrays can be two-dimensional (2D) so as to exhibit a single deck (e.g., a single tier, a single level) of the memory cells, or can be three-dimensional (31)) so as to exhibit multiple decks (e.g., multiple levels, multiple tiers) of the memory cells.

Control logic devices within a base control logic structure underlying a memory array of a memory device have been used to control operations (e.g., access operations, read operations, write operations) of the memory cells of the memory device. An assembly of the control logic devices may be provided in electrical communication with the memory cells of the memory array by way of routing and interconnect structures. However, processing conditions (e.g., temperatures, pressures, materials) for the formation of the memory array over the base control logic structure can limit the configurations and performance of the control logic devices within the base control logic structure. In addition, the quantities, dimensions, and arrangements of the different control logic devices employed within the base control logic structure can also undesirably impede reductions to the size (e.g., horizontal footprint) of the memory device, and/or improvements in the performance (e.g., faster memory cell ON/OFF speed, lower threshold switching voltage requirements, faster data transfer rates, lower power consumption) of the memory device. Furthermore, as the density and complexity of the memory array have increased, so has the complexity of the control logic devices. In some instances, the control logic devices consume more real estate than the memory devices, reducing the memory density of the memory device.

### BRIEF DESCRIPTION OF THE DRAWINGS

FIGS. 1A-1C are simplified, partial isometric vertical cross-sectional views illustrating different processing stages of a method of forming a microelectronic device, in accordance with embodiments of the disclosure.

FIGS. 2A and 2B are simplified, top-down views of a bonded, cruciform contact structure for the microelectronic device shown in FIG. 1C, in accordance with embodiments of the disclosure.

FIGS. 3A-3C are simplified, partial vertical cross-sectional views of a first microelectronic device structure (FIG. 3A) and of a second microelectronic device structure (FIGS. 3B and 3C) that may be employed in the method of forming a microelectronic device described with reference to FIGS. 1A-1C, in accordance with embodiments of the disclosure.

FIG. 4 is a schematic block diagram of an electronic system, in accordance with embodiments of the disclosure.

### DETAILED DESCRIPTION

The following description provides specific details, such as material types, material thicknesses, and processing conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the semiconductor industry. In addition, the description provided herein does not form a complete process flow for manufacturing a microelectronic device (e.g., a memory device), apparatus, or electronic system, or a complete microelectronic device structure, apparatus, or electronic system. The structures described below do not form a complete microelectronic device structure, apparatus, or electronic system. Only those process acts and structures necessary to understand the embodiments described herein are described in detail below. Additional acts to form a complete microelectronic device, apparatus, or electronic system from the structures may be performed by conventional techniques.

Drawings presented herein are for illustrative purposes only and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

The materials described herein may be formed by conventional techniques including, but not limited to, spin coating, blanket coating, chemical vapor deposition (CVD), atomic material deposition (ALD), plasma enhanced ALD, physical vapor deposition (PVD), plasma enhanced chemical vapor deposition (PECVD), or low-pressure chemical vapor deposition (LPCVD). Alternatively, the materials may be grown in situ. Depending on the specific material to be formed, the technique for depositing or growing the material may be selected by a person of ordinary skill in the art. The removal of materials may be accomplished by any suitable technique including, but not limited to, etching, abrasive planarization (e.g., chemical-mechanical planarization), or other known methods unless the context indicates otherwise.

As used herein, the singular forms following “a,” “an,” and “the” are intended to include the plural forms as well, unless the context clearly indicates otherwise.

As used herein, the term “may” with respect to a material, structure, feature, or method act indicates that such is contemplated for use in implementation of an embodiment of the disclosure, and such term is used in preference to the more restrictive term “is” so as to avoid any implication that other compatible materials, structures, features, and methods usable in combination therewith should or must be excluded.

As used herein, the term “configured” refers to a size, shape, material composition, orientation, and arrangement of one or more of at least one structure and at least one apparatus facilitating operation of one or more of the structure and the apparatus in a predetermined way.

As used herein, the terms “longitudinal,” “vertical,” “lateral,” and “horizontal” are in reference to a major plane of a substrate (e.g., base material, base structure, base construction, etc.) in or on which one or more structures and/or features are formed and are not necessarily defined by Earth's gravitational field. A “lateral” or “horizontal” direction is a direction that is substantially parallel to the major plane of the substrate, while a “longitudinal” or “vertical” direction is a direction that is substantially perpendicular to the major plane of the substrate. The major plane of the substrate is defined by a surface of the substrate having a relatively large area compared to other surfaces of the substrate. With reference to the figures, a “horizontal” or “lateral” direction may be perpendicular to an indicated “Z” axis and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, the term “substantially” in reference to a given parameter, property, or condition means and includes to a degree that one skilled in the art would understand that the given parameter, property, or condition is met with a small degree of variance, such as within acceptable manufacturing tolerances. By way of example, depending on the particular parameter, property, or condition that is substantially met, the parameter, property, or condition may be at least 90.0% met, at least 95.0% met, at least 99.0% met, or even at least 99.9% met.

As used herein, the term “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, features (e.g., regions, materials, structures, devices) described as “neighboring” one another means and includes features of the disclosed identity (or identities) that are located most proximate (e.g., closest to) one another. Additional features (e.g., additional regions, additional materials, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the term “memory device” means and includes microelectronic device structures exhibiting memory functionality, but not necessarily limited to memory functionality. Stated another way, and by way of example only, the term “memory device” means and includes not only conventional memory (e.g., conventional volatile memory, such as conventional DRAM; conventional non-volatile memory, such as conventional NAND memory), but also includes an application specific integrated circuit (ASIC) (e.g., a system on a chip (SoC)), a microelectronic device structure combining logic and memory, and a graphics processing unit (GPU) incorporating memory.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively doped polysilicon, conductively doped germanium (Ge), conductively doped silicon germanium (SiGe)). In addition, a “conductive structure” means and includes a structure formed of and including a conductive material.

As used herein, “insulative material” means and includes electrically insulative material, such as one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). In addition, an “insulative structure” means and includes a structure formed of and including an insulative material.

As used herein, “semiconductor material” or “semiconductive material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

As used herein, the phrase “coupled to” refers to structures operatively connected with each other, such as electrically connected through a direct Ohmic connection or through an indirect connection (e.g., by way of another structure).

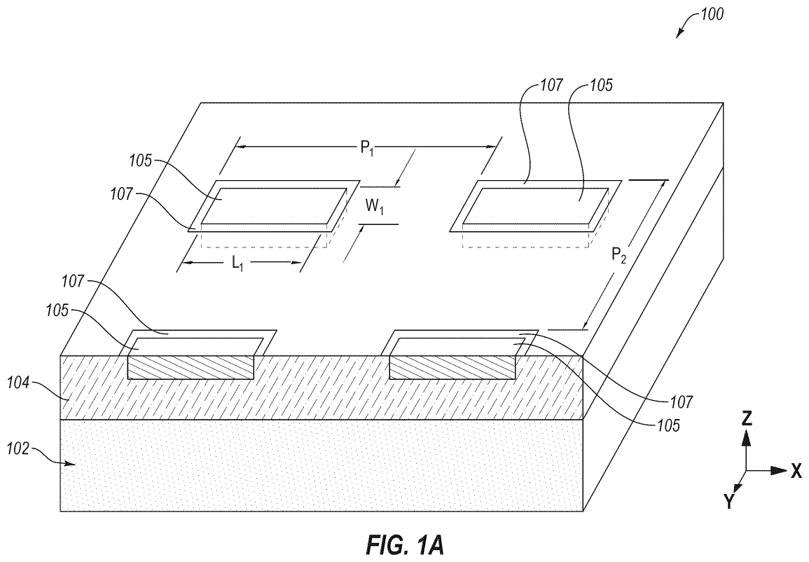

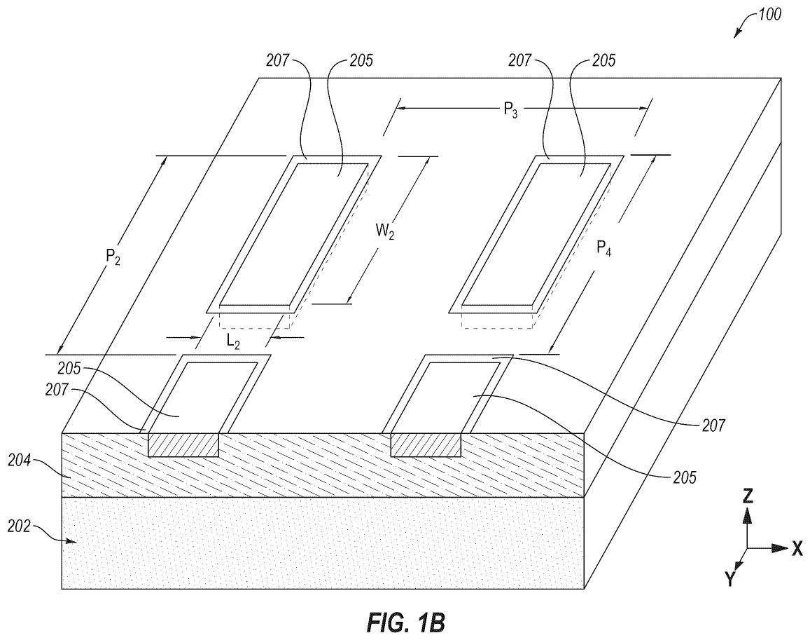

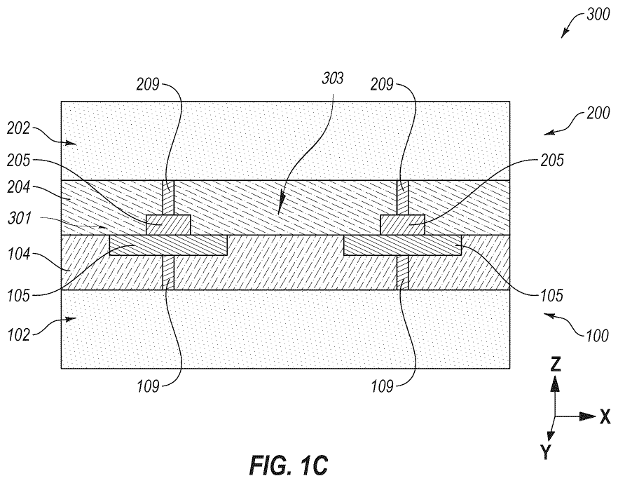

FIGS. 1A-1C are simplified, partial isometric vertical cross-sectional views illustrating different processing stages of method of forming a microelectronic device (e.g., a memory device, such as a non-volatile memory device, or a volatile memory device), in accordance with embodiments of the disclosure. With the description provided below, it will be readily apparent to one of ordinary skill in the art that the methods and structures described herein may be used in various devices and electronic systems.

Referring to FIG. 1A, a first microelectronic device structure 100 (e.g., a first wafer) may be formed to include a first base structure 102 and a first dielectric material 104. The first microelectronic device structure 100 may also include additional features (e.g., materials, structures, regions, devices), as described in further detail below.

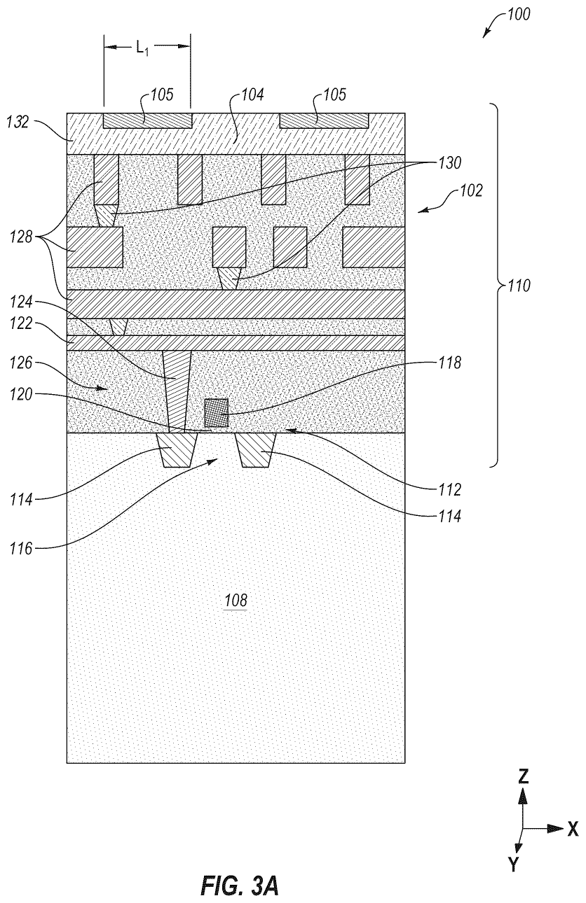

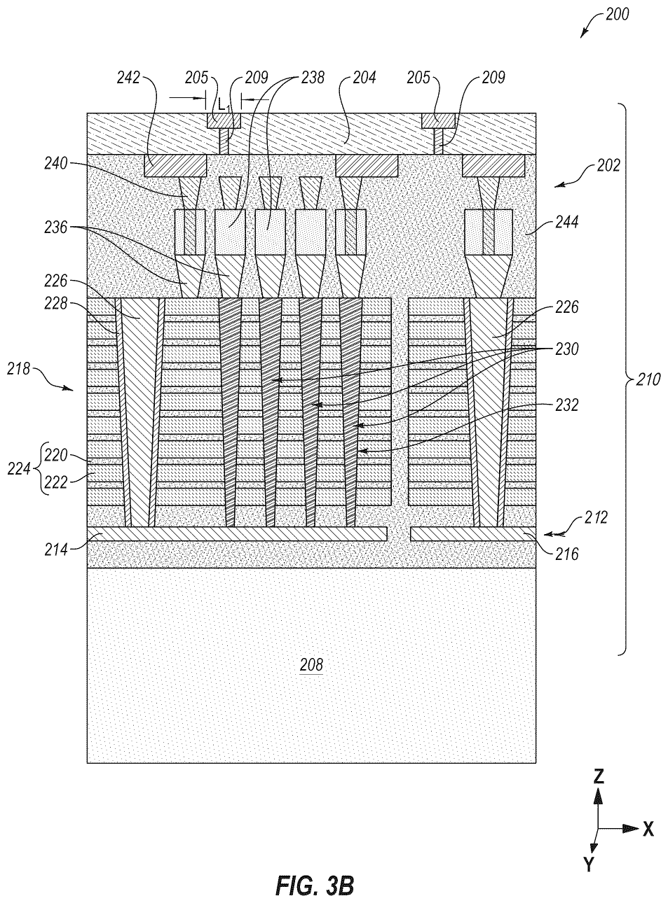

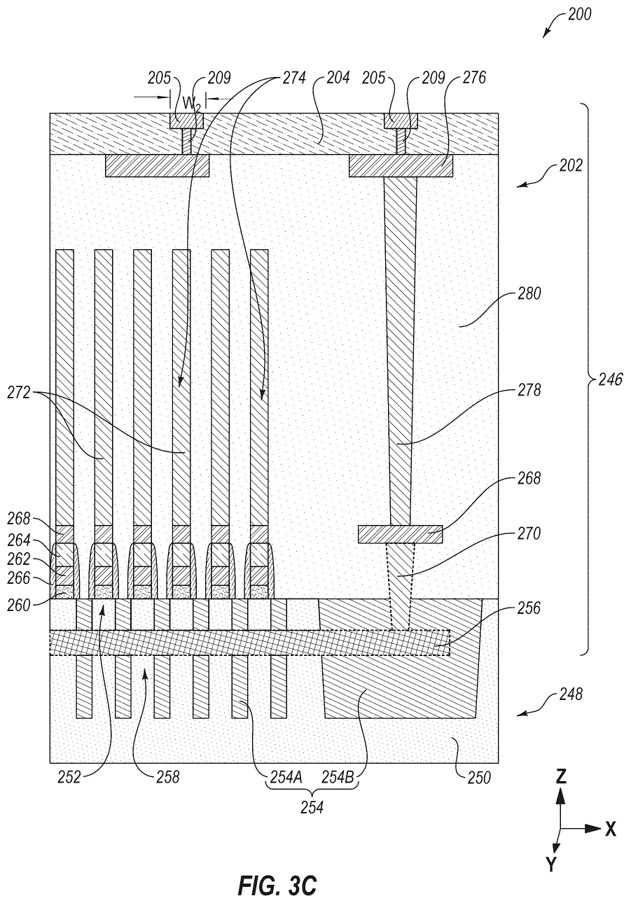

The first base structure 102 may comprise base construction upon which additional features (e.g., materials, structures, devices) of the first microelectronic device structure 100 are formed. As a non-limiting example, the first base structure 102 may comprise a control circuitry structure including control logic circuitry. An embodiment of one such configuration for the first microelectronic device structure 100 is described in further detail below with reference to FIG. 3A. As another non-limiting example, the first base structure 102 may comprise a memory array structure (e.g., a non-volatile memory array structure, a volatile memory array structure) including an array of memory cells (e.g., an array of non-volatile memory cells, an array of volatile memory cells). An embodiment of one such configuration for the first microelectronic device structure 100, including an array of non-volatile memory cells, is described in further detail below with reference to FIG. 3B. An additional embodiment of one such configuration for the first base structure 102, including an array of non-volatile memory cells, is described in further detail below with reference to FIG. 3C.

The first dielectric material 104 may be formed of and include at least one dielectric material including, but not limited to, one or more of at least one dielectric oxide material (e.g., a silicon oxide (SiOₓ)), at least one dielectric nitride material (e.g., a silicon nitride (SiN_{y})), at least one oxynitride material (e.g., a silicon oxynitride (SiOₓN_{y})), and at least one carboxynitride material (e.g., a silicon carboxynitride (SiOₓC_{z}N_{y})). In one non-limiting example, the first dielectric material 104 is formed of and includes SiOₓ (e.g., SiO₂).

Still referring to FIG. 1A, the first microelectronic device structure 100 may further include one or more first conductive contact bars 105 at least partially surrounded by the first dielectric material 104. As shown in FIG. 1A, in some embodiments, side surfaces (e.g., sidewalls) and bottom surfaces (e.g., floors) of the first conductive contact bars 105 are substantially surrounded by the first dielectric material 104. Each of the first conductive contact bars 105 may be substantially horizontally surrounded by a keepout region 107 (also referred to herein as an “isolation region”) of the first dielectric material 104 wherein no other conductive structures are provided within the first dielectric material 104. Upper surfaces (e.g., top surfaces) of the first conductive contact bars 105 may be substantially free of the first dielectric material 104 thereon or thereover. In some embodiments, upper surfaces of the first conductive contact bars 105 and the first dielectric material 104 together at least partially form a top surface of the first microelectronic device structure 100. The upper surfaces of the first conductive contact bars 105 and the first dielectric material 104 may be formed to be substantially coplanar with one another.

The first conductive contact bars 105 may respectively be rectangular in shape with a length L₁ in a first horizontal direction (e.g., the X-direction) greater than a width W₁ in a second horizontal direction (e.g., the Y-direction). By way of non-limiting example, a length L₁ of an individual first conductive contact bar 105 in the X-direction may be greater than or equal to about two times (2×) a width W₁ of the first conductive contact bar 105 in the Y-direction, such as greater than or equal to about three times (3×) the width W₁, or greater than or equal to about four times (4×) the width W₁. Each of the first conductive contact bars 105 may have substantially the same length L₁ as each other of the first conductive contact bars 105, or at least one of the first conductive contact bars 105 may have a different length L₁ than at least one other of the first conductive contact bars 105. In addition, each of the first conductive contact bars 105 may have substantially the same width W₁ as each other of the first conductive contact bars 105, or at least one of the first conductive contact bars 105 may have a different width W₁ than at least one other of the first conductive contact bars 105.

In the embodiment shown in FIG. 1A, the first conductive contact bars 105 are horizontally oriented substantially identically, with relatively larger horizontal dimensions (e.g., lengths L₁) thereof horizontally extending in parallel in the X-direction. In other embodiments, one or more of first conductive contact bars 105 are horizontally oriented different than one or more other of the first conductive contact bars 105. For example, one or more of the first conductive contact bars 105 may individually have a relatively larger horizontal dimension (e.g., length L₁) thereof that horizontally extends parallel to the Y-direction.

As described in further detail below, first conductive contact bars 105 horizontally neighboring one another in the X-direction may have a first pitch P₁; and first conductive contact bars 105 horizontally neighboring one another in the Y-direction may have a second pitch P₂ in the Y-direction. The first pitch P₁ may be substantially the same (e.g., substantially uniform) for all first conductive contact bars 105 horizontally neighboring one another in the X-direction; or a first pitch P₁ between at least two of the first conductive contact bars 105 horizontally neighboring one another in the X-direction may be different than a first pitch P₁ between at least two other of the first conductive contact bars 105 horizontally neighboring one another in the X-direction. In addition, the second pitch P₂ may be substantially the same (e.g., substantially uniform) for all first conductive contact bars 105 horizontally neighboring one another in the Y-direction; or a second pitch P₂ between at least two of the first conductive contact bars 105 horizontally neighboring one another in the Y-direction may be different than a second pitch P₂ between at least two other of the first conductive contact bars 105 horizontally neighboring one another in the Y-direction.

The first conductive contact bars 105 may respectively be formed of and include conductive material. In some embodiments, the first conductive contact bars 105 are individually formed of and include one or more of W, Ru, Mo, Cu, and TiN_{y}.

Referring to FIG. 1B, a second microelectronic device structure 200 (e.g., a second wafer) may be formed to include a second base structure 202 and a second dielectric material 204. The second microelectronic device structure 200 may include additional features (e.g., materials, structures, regions, devices), as described in further detail below.

The second base structure 202 may comprise base construction upon which additional features (e.g., materials, structures, devices) of the second microelectronic device structure 200 are formed. As a non-limiting example, the second base structure 202 may comprise a control circuitry structure including control logic circuitry. An embodiment of one such configuration for the second microelectronic device structure 200 is described in further detail below with reference to FIG. 3A. As another non-limiting example, the second base structure 202 may comprise a memory array structure (e.g., a non-volatile memory array structure, a volatile memory array structure) including an array of memory cells (e.g., an array of non-volatile memory cells, an array of volatile memory cells). An embodiment of one such configuration for the second microelectronic device structure 200, including an array of non-volatile memory cells, is described in further detail below with reference to FIG. 3B. An additional embodiment of one such configuration for the second base structure 202, including an array of non-volatile memory cells, is described in further detail below with reference to FIG. 3C.

The second dielectric material 204 may be formed of and include at least one dielectric material including, but not limited to, one or more of at least one dielectric oxide material (e.g., SiOₓ), nitride material (e.g., a silicon nitride (SiN_{y})), at least one dielectric oxynitride material (e.g., a SiOₓN_{y}), and at least one dielectric carboxynitride material (e.g., SiOₓC_{z}N_{y}). In one non-limiting example, the second dielectric material 204 is formed of and includes SiOₓ (e.g., SiO₂).

Still referring to FIG. 1B, the second microelectronic device structure 200 may further include one or more second conductive contact bars 205 at least partially surrounded by the second dielectric material 204. As shown in FIG. 1B, in some embodiments, side surfaces (e.g., sidewalls) and bottom surfaces (e.g., floors) of the second conductive contact bars 205 are substantially surrounded by the second dielectric material 204. Each of the second conductive contact bars 205 may be substantially horizontally surrounded by an additional keepout region 207 (also referred to herein as an “additional isolation region”) of the second dielectric material 204 wherein no other conductive structures are provided within the second dielectric material 204. Upper surfaces (e.g., top surfaces) of the second conductive contact bars 205 may be substantially free of the second dielectric material 204 thereon or thereover. In some embodiments, upper surfaces of the second conductive contact bars 205 and the second dielectric material 204 together at least partially form a top surface of the second microelectronic device structure 200. The upper surfaces of the second conductive contact bars 205 and the second dielectric material 204 may be formed to be substantially coplanar with one another.

The second conductive contact bars 205 may respectively be rectangular in shape with a length L₂ in a first horizontal direction (e.g., the X-direction) less than a width W₂ in a second horizontal direction (e.g., the Y-direction). By way of non-limiting example, a length L₂ of an individual second conductive contact bar 205 in the X-direction may be less than or equal to about one-half (0.5×) a width W₂ of the second conductive contact bar 205 in the Y-direction, such as less than or equal to about one-third (0.33×) the width W₂, or less than or equal to about one-fourth (0.25×) the width W₂. Each of the second conductive contact bars 205 may have substantially the same length L₂ as each other of the second conductive contact bars 205, or at least one of the second conductive contact bars 205 may have a different length L₂ than at least one other of the second conductive contact bars 205. In addition, each of the second conductive contact bars 205 may have substantially the same width W₂ as each other of the second conductive contact bars 205, or at least one of the second conductive contact bars 205 may have a different width W₂ than at least one other of the second conductive contact bars 205.

In some embodiments, the width W₂ of an individual second conductive contact bar 205 is substantially equal to the length L₁ of an individual first conductive contact bar 105 (FIG. 1A). Furthermore, in some embodiments, the length L₂ of an individual second conductive contact bar 205 is substantially equal to the width W₁ of an individual first conductive contact bar 105 (FIG. 1A).

In some embodiments, a horizontal area of an individual second conductive contact bar 205 is substantially equal to a horizontal area of an individual first conductive contact bar 105 (FIG. 1A). In additional embodiments, the horizontal area of an individual second conductive contact bar 205 is different than (e.g., less than, greater than) the horizontal area of an individual first conductive contact bar 105 (FIG. 1A).

In the embodiment shown in FIG. 1B, the second conductive contact bars 205 are horizontally oriented substantially identically, with relatively larger horizontal dimensions (e.g., widths W₂) thereof horizontally extending in parallel in the Y-direction. In other embodiments, one or more of second conductive contact bars 205 are horizontally oriented different than one or more other of the second conductive contact bars 205. For example, one or more of the second conductive contact bars 205 may individually have a relatively larger horizontal dimension (e.g., width W₂) thereof that horizontally extends parallel to the X-direction.

As described in further detail below, second conductive contact bars 205 horizontally neighboring one another in the X-direction may have a first additional pitch P₃; and second conductive contact bars 205 horizontally neighboring one another in the Y-direction may have a second additional pitch P₄ in the Y-direction. The first additional pitch P₃ may be substantially the same (e.g., substantially uniform) for all second conductive contact bars 205 horizontally neighboring one another in the X-direction; or a first additional pitch P₃ between at least two of the second conductive contact bars 205 horizontally neighboring one another in the X-direction may be different than a first additional pitch P₃ between at least two other of the second conductive contact bars 205 horizontally neighboring one another in the X-direction. In addition, the second additional pitch P₄ may be substantially the same (e.g., substantially uniform) for all second conductive contact bars 205 horizontally neighboring one another in the Y-direction; or a second additional pitch P₄ between at least two of the second conductive contact bars 205 horizontally neighboring one another in the Y-direction may be different than a second additional pitch P₄ between at least two other of the second conductive contact bars 205 horizontally neighboring one another in the Y-direction.

The second conductive contact bars 205 may respectively be formed of and include conductive material. A material composition of each of the second conductive contact bars 205 may be substantially the same as a material composition of each of the first conductive contact bars 105 (FIG. 1A) of the first microelectronic device structure 100 (FIG. 1A); or the material composition of at least one of the second conductive contact bars 205 may be different than the material composition of at least one of the first conductive contact bars 105 (FIG. 1A) of the first microelectronic device structure 100 (FIG. 1A). In some embodiments, the second conductive contact bars 205 are individually formed of and include one or more of W, Ru, Mo, Cu, and TiN_{y}.

Referring next to FIG. 1C, the second microelectronic device structure 200 may be vertically inverted (e.g., flipped) and attached (e.g., bonded) to the first microelectronic device structure 100 to form at least a portion of a microelectronic device 300 (e.g., a memory device). As shown in FIG. 1C, the microelectronic device 300 may be formed to include an assembly of the first microelectronic device structure 100 (including the first base structure 102 and the first dielectric material 104 thereof); and the second microelectronic device structure 200 (including the second base structure 202 and the second dielectric material 204 thereof), as vertically inverted, above the first microelectronic device structure 100. Alternatively, the first microelectronic device structure 100 may be vertically inverted (e.g., flipped) and attached (e.g., bonded) to the second microelectronic device structure 200 to form the microelectronic device 300.

The first microelectronic device structure 100 and the second microelectronic device structure 200 are bonded together at least by way of conductor-to-conductor (e.g., metal-to-metal) bonding between the first conductive contact bars 105 and the second conductive contact bar 205. An individual first conductive contact bar 105 of the first microelectronic device structure 100 may be bonded to an individual second conductive contact bar 205 of the second microelectronic device structure 200 to form an individual cruciform contact structure 301 (e.g., a cross-shaped contact structure, an X-shaped contact structure). The first conductive contact bar 105 may form a first portion (e.g., a lower portion) of the cruciform contact structure 301, and the second conductive contact bar 205 may form an upper portion of the cruciform contact structure 301. For an individual cruciform contact structure 301, the first conductive contact bar 105 thereof may be integral and continuous with the second conductive contact bar 205 thereof. In additional embodiments, the first microelectronic device structure 100 and the second microelectronic device structure 200 are further bonded together at least by way of dielectric-to-dielectric (e.g., oxide-to-oxide, nitride-to-nitride, oxynitride-to-oxynitride) bonding between the first dielectric material 104 and the second dielectric material 204.

As shown in FIG. 1C, due to the first pitch P₁ in the X-direction between first conductive contact bars 105 horizontally neighboring one another in the X-direction and the first additional pitch P₃ in the X-direction between second conductive contact bars 205 horizontally neighboring one another in the X-direction, the microelectronic device 300 include so-called “open” regions 303 horizontally interposed in the X-direction between cruciform contact structures 301 horizontally neighboring one another in the X-direction. Similarly, due to the second pitch P₂ (FIG. 1A) in the Y-direction between first conductive contact bars 105 horizontally neighboring one another in the Y-direction and the second additional pitch P₄ (FIG. 1B) in the Y-direction between second conductive contact bars 205 horizontally neighboring one another in the Y-direction, the microelectronic device 300 includes additional open regions horizontally interposed in the Y-direction between cruciform contact structures 301 horizontally neighboring one another in the Y-direction. In some embodiments, such open regions 303 and/or such additional open regions may be employed for the formation of additional features (e.g., structures, such as contact structures and/or routing structures; devices; materials) for the microelectronic device 300 following the processing stage depicted in FIG. 1C.

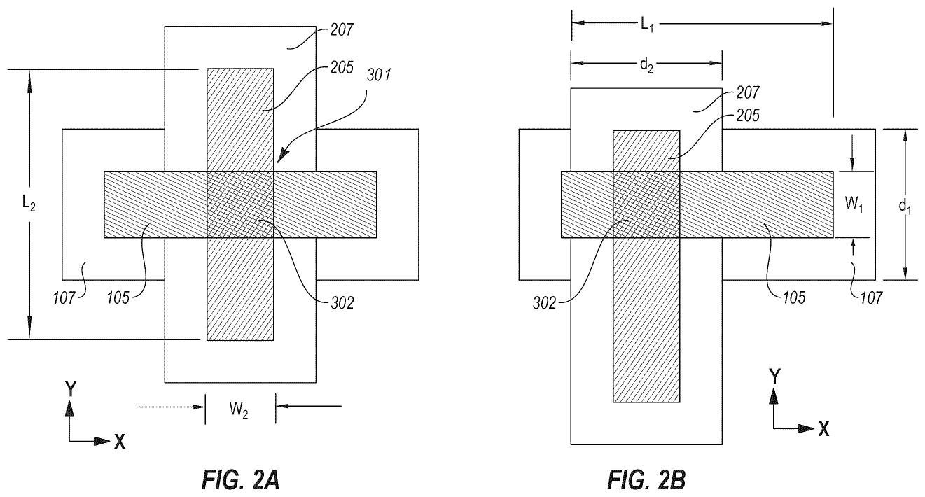

Referring now collectively to FIGS. 2A and 2B, shown are simplified, top-down views of different embodiments of a cruciform contact structure 301 for the microelectronic device 300 shown in FIG. 1C. As shown in each of FIGS. 2A and 2B, the first conductive contact bar 105 and the second conductive contact bar 205 of an individual cruciform contact structure 301 are horizontally oriented substantially perpendicular to one another.

Referring to FIG. 2A, in some embodiments, for an individual cruciform contact structure 301, a horizontal center (e.g., in the X-direction and the Y-direction) of the first conductive contact bar 105 thereof may be substantially horizontally aligned with a horizontal center (e.g., in the X-direction and the Y-direction) of the second conductive contact bar 205 thereof. Accordingly, a connection area 302 (e.g., bonded area) of the first conductive contact bar 105 and the second conductive contact bar 205 may be substantially horizontally centered within the cruciform contact structure 301.

Referring next to FIG. 2B, in additional embodiments, for an individual cruciform contact structure 301, a horizontal center (e.g., in the X-direction and the Y-direction) of the first conductive contact bar 105 thereof may be horizontally offset (e.g., in one or more of the X-direction and the Y-direction) from a horizontal center (e.g., in the X-direction and the Y-direction) of the second conductive contact bar 205 thereof. Accordingly, the connection area 302 (e.g., bonded area) of the first conductive contact bar 105 and the second conductive contact bar 205 may not be substantially horizontally centered within the cruciform contact structure 301.

Referring collectively to FIGS. 2A and 2B, despite the aforementioned differences in the alignments of the horizontal centers of the first conductive contact bar 105 and the second conductive contact bar 205 in the embodiments of FIGS. 2A and 2B, a horizontal size (e.g., horizontal area) of the connection area 302 of the cruciform contact structure 301 shown in FIG. 2A is substantially the same as a horizontal size (e.g., horizontal area) of the connection area 302 of the cruciform contact structure 301 shown in FIG. 2B. Namely, the methods and structures of the disclosure facilitate substantially consistent connection areas 302 of the cruciform contact structures 301 despite horizontal potential misalignments between the first conductive contact bar 105 and the second conductive contact bar 205 of respective cruciform contact structures 301.

Referring to FIG. 2B, for an individual cruciform contact structure 301, a first combined width d₁ represents a total width, in the Y-direction, of a first conductive contact bar 105 and the keepout regions 107 to both sides thereof; and a second combined width d₂ represents a total width, in the X-direction, of a second conductive contact bar 205 and the keepout regions 207 to both sides thereof. The first combined width d₁ horizontally extends parallel to, but is smaller than, the second additional pitch P₄ previously described with reference to FIG. 1B. The second combined width d₂ horizontally extends parallel to, but is smaller than, the first pitch P₁ previously described with reference to FIG. 1A. These differences facilitate open spaces horizontally neighboring the cruciform contact structure 301, which may accommodate additional features placement as relative to conventional configurations employing conventional connector structures (e.g., conventional contact pads). Partly because of these differences between pitches and widths, the configurations of the cruciform contact structures 301 of the disclosure permit reductions in pitches (e.g., in the X-direction, in the Y-direction) between horizontally neighboring cruciform contact structures 301 as compared to conventional bond pad structures, permitted a relatively greater density of cruciform contact structures 301 per unit area. In addition, the relatively greater tolerance for horizontal misalignment(s) of the first conductive contact bar 105 and the second conductive contact bar 205 permits pitch reduction between neighboring cruciform contact structures 301 as compared to conventional connector structure configurations without reducing chip yield.

Referring collectively to FIGS. 2A and 2B, the configurations of the cruciform contact structures 301 (including configurations of the first conductive contact bars 105 and second conductive contact bars 205 thereof) provide reliable connections between the first microelectronic device structure 100 (FIGS. 1A and 1C) and the second microelectronic device structure 200 (FIGS. 1B and 1C), while also requiring relatively less of the horizontal area within the microelectronic device 300 (FIG. 1C) as compared to conventional configurations. For example, as the first pitch P₁ and the second additional pitch P₄ described with reference to FIGS. 1A-1C horizontally extend orthogonal to one another, is a relatively greater horizontally offset between similarly oriented conductive contact bars (e.g., first conductive contact bars 105 or second conductive contact bars 205) of horizontally neighboring (e.g., in the X-direction, in the Y-direction) cruciform contact structures 301, providing relatively more horizontal space for additional features of the microelectronic device 300 (FIG. 1C).

As described herein, the connections between the first conductive contact bars 105 and second conductive contact bars 205 may facilitate enhanced connectivity as compared to conventional connector structures (e.g., conventional bond pads). Because the cruciform contact structures 301 individually have a consistent connection area 302 between the first conductive contact bars 105 and second conductive contact bars 205 thereof, the electrical properties (e.g., resistance) of the cruciform contact structures 301 may be relatively more consistent and predictable as compared to conventional connector structure configurations. In addition, by reducing a horizontal footprint of an individual cruciform contact structure 301 relative to that of a conventional connector structure, horizontal areas of the keepout regions 107, 207 surrounding the cruciform contact structure 301 may be relatively smaller than conventional keepout regions surrounding conventional connector structures. In some embodiments the keepout regions 107, 207, respectively, have a narrowest horizontal dimension within a range of from about 20% to about 40% (e.g., from about 25% to about 30%, about 25%) of a narrowest horizontal dimension of the conductive contact bars 105, 205 horizontally surrounded thereby.

Following the attachment of the second microelectronic device structure 200 to the first microelectronic device structure 100, the microelectronic device 300 may be subjected to additional processing, as desired. As a non-limiting example, interconnect structures (e.g., contact structures) may be formed within the microelectronic device 300 to couple features (e.g., structures, materials, devices) of the second microelectronic device structure 200 to additional features (e.g., additional structures, additional materials, additional devices) of the first microelectronic device structure 100. As an additional non-limiting example, so-called “back-end-of-line” (BEOL) structures (e.g., routing structures, pad structures, contact structures) may be formed over the second microelectronic device structure 200, and may be coupled to features (e.g., structures, materials, devices) of the second microelectronic device structure 200 and/or the first microelectronic device structure 100, as desired. While FIG. 1C shows that the microelectronic device 300 as being formed upon the attachment of the second microelectronic device structure 200 to the first microelectronic device structure 100, it will be understood that such additional processing may be implemented to finalize or ready the microelectronic device 300 for inclusion in a relatively larger device and/or electronic system.

As previously described herein, the first microelectronic device structure 100 and the second microelectronic device structure 200 may be formed to have desired configurations, including desired configurations of the first base structure 102 and the second base structure 202 thereof, respectively. In this regard, FIGS. 3A through 3C are simplified, partial vertical cross-sectional views showing non-limiting examples of different configurations that may be employed for the first microelectronic device structure 100 and the second microelectronic device structure 200. FIG. 3A shows a simplified, partial vertical cross-sectional view of the first microelectronic device structure 100, wherein the first base structure 102 thereof is configured as a control circuitry structure. FIG. 3B shows a simplified, partial vertical cross-sectional view of the second microelectronic device structure 200, wherein the second base structure 202 thereof is configured as a non-volatile memory array structure (e.g., a 3D NAND Flash memory array structure) including vertically extending strings of non-volatile memory cells. FIG. 3C shows a simplified, partial vertical cross-sectional view of the second microelectronic device structure 200, wherein the second base structure 202 thereof is configured as a volatile memory array structure (e.g., DRAM memory array structure) including volatile memory cells (e.g., DRAM cells). While the configuration shown in FIG. 3A is described in regard to the first microelectronic device structure 100 and the configurations shown in FIGS. 3B and 3C are described in regard to the second microelectronic device structure 200, it will be understood that the configuration shown in FIG. 3A may be employed in the second microelectronic device structure 200 and/or either of the configurations shown in FIGS. 3B and 3C may be employed in the first microelectronic device structure 100.

Referring first to FIG. 3A, the first base structure 102 of the first microelectronic device structure 100 may be formed as a control circuitry structure to include control logic circuitry therein. The first base structure 102 may vertically underlie the first dielectric material 104 and may include a semiconductor substrate 108 and a control circuitry region 110 (e.g., a control logic region) at least partially overlying the semiconductor substrate 108. First conductive contact bars 105 may be positioned in the first dielectric material 104 and connected to conductive leads 109 that connect to microelectronic components in other materials of the first microelectronic device structure 100. The control circuitry region 110 may include transistors 112, first routing structures 122, first contact structures 124, second routing structures 128, second contact structures 130, and an isolation material 132. The transistors 112, the first routing structures 122, and the first contact structures 124 may form control logic circuitry of various control logic devices 126 of the control circuitry region 110, as described in further detail below.

The semiconductor substrate 108 may comprise a semiconductor structure (e.g., a semiconductor wafer) or a base semiconductor material on a supporting structure. For example, semiconductor substrate 108 may comprise a conventional silicon substrate (e.g., a conventional silicon wafer) or another bulk substrate comprising a semiconductor material. In some embodiments, semiconductor substrate 108 comprises a silicon wafer. In addition, semiconductor substrate 108 may include one or more materials, structures, and/or regions formed therein and/or thereon. For example, semiconductor substrate 108 may include conductively doped regions and undoped regions.

The transistors 112 of the control circuitry region 110 may be formed to vertically intervene between portions of the semiconductor substrate 108 and the first routing structures 122 of the control circuitry region 110. The transistors 112 may respectively include conductively doped regions 114 (e.g., serving as source regions and drain regions of the transistors 112) within the semiconductor substrate 108, a channel region 116 within the semiconductor substrate 108 and horizontally interposed between the conductively doped regions 114, a gate structure 118 (e.g., gate electrode) vertically overlying the channel region 116, and gate dielectric material 120 (e.g., dielectric oxide material) vertically interposed between the gate structure 118 and the channel region 116.

For the transistors 112 of the control circuitry region 110, the conductively doped regions 114 within the semiconductor substrate 108 may be doped with one or more desirable dopants (e.g., chemical species). In some embodiments, the conductively doped regions 114 of an individual transistor 112 within the control circuitry region 110 are doped with at least one N-type dopant (e.g., one or more of phosphorus, arsenic, antimony, and bismuth). In some of such embodiments, channel region 116 of the transistor 112 is doped with at least one P-type dopant (e.g., one or more of boron, aluminum, and gallium). In some other of such embodiments, channel region 116 of the transistor 112 is substantially undoped. In additional embodiments, the conductively doped regions 114 of an individual transistor 112 within the control circuitry region 110 are doped with at least one P-type dopant (e.g., one or more of boron, aluminum, and gallium). In some of such additional embodiments, channel region 116 of transistor 112 is doped with at least one N-type dopant (e.g., one or more of phosphorus, arsenic, antimony, and bismuth). In some other such additional embodiments, channel region 116 of transistor 112 is substantially undoped.

The gate structures 118 may individually horizontally extend (e.g., in the Y-direction) between and be employed by multiple transistors 112 of the control circuitry region 110. Gate structures 118 may be formed of and include conductive material. By way of non-limiting example, the gate structures 118 may be formed of and include one or more of at least one metal, at least one alloy, and at least one conductive metal-containing material (e.g., a conductive metal nitride, a conductive metal silicide, a conductive metal carbide, a conductive metal oxide).

Still referring to FIG. 3A, the first contact structures 124 vertically overlie and contact (e.g., physical contact, electrical contact) the conductively doped regions 114 of the transistors 112. In some embodiments, an individual first contact structure 124 vertically overlies, horizontally overlaps, and physically contacts one of the conductively doped regions 114 of an individual transistor 112. In addition, the first routing structures 122 may vertically overlie the transistors 112. As shown in FIG. 3A, some of the first routing structures 122 may be coupled to the first contact structures 124 (and, hence, the transistors 112). The first contact structures 124 and the first routing structures 122 may respectively be formed of and include conductive material. In some embodiments, the first contact structures 124 and the first routing structures 122 are individually formed of and include one or more of W, Ru, Mo, and TiN_{y}.

As previously mentioned, transistors 112, the first routing structures 122, and the first contact structures 124 may form control logic circuitry of various control logic devices 126 of the control circuitry region 110. In some embodiments, the control logic devices 126 comprise complementary metal-oxide-semiconductor (CMOS) circuitry. The control logic devices 126 may be configured to control various operations of other components (e.g., memory cells, such as non-volatile memory cells or volatile memory cells) of the microelectronic device 300 (FIG. 1C) to be formed using the first microelectronic device structure 100 and the second microelectronic device structure 200 (FIG. 1B) through the process previously described herein. As a non-limiting example, depending on configuration of the second microelectronic device structure 200 (FIG. 1B) to be attached to the first microelectronic device structure 100, the control logic devices 126 may include one or more of charge pumps (e.g., V_{CCP} charge pumps, V_{NEGWL} charge pumps, DVC2 charge pumps), delay-locked loop (DLL) circuitry (e.g., ring oscillators), V_{dd} regulators, drivers (e.g., string drivers, main word line drivers (MWD), sub word line drivers (SWD)), page buffers, decoders (e.g., local deck decoders, column decoders, row decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry, row repair circuitry), I/O devices (e.g., local I/O devices), memory test devices, array multiplexers (MUX), error checking and correction (ECC) devices, self-refresh/wear leveling devices, and other chip/deck control circuitry. Different horizontal sub-regions of the control circuitry region 110 may have different control logic devices 126 formed within horizontal areas thereof.

One or more tiers (e.g., at least two tiers, at least three tiers) including second routing structures 128 may vertically overlie the first routing structures 122 (and, hence, the control logic devices 126). In addition, the second contact structures 130 may couple different second routing structures 128 with one another and/or with different first routing structures 122, as desired. Some of the second routing structures 128 may be coupled to some other of the second routing structures 128 by way of some of the second contact structures 130; and some of the second routing structures 128 may be coupled to some of the first routing structure 122 by way of some others of the second contact structures 130. The second routing structures 128 and the second contact structures 130 may respectively be formed of and include conductive material. In some embodiments, the second routing structures 128 and the second contact structures 130 are individually formed of and include one or more of W, Ru, Mo, and TiN_{y}.

Still referring to FIG. 3A, the isolation material 132 may be formed to cover and surround portions of the transistors 112, the first routing structures 122, the first contact structures 124, the second routing structures 128, and the second contact structures 130. In some embodiments, the isolation material 132 is formed such that an upper surface thereof is substantially coplanar with upper surfaces of uppermost ones of the second routing structures 128 of the first microelectronic device structure 100. Accordingly, the first dielectric material 104 may be formed on upper surfaces of the isolation material 132 and the uppermost ones of the second routing structures 128. In additional embodiments, the isolation material 132 is formed to substantially cover the upper surfaces of the uppermost ones of the second routing structures 128. Accordingly, the first dielectric material 104 may be formed only on an upper surface of the isolation material 132. The isolation material 132 may be formed of and include insulative material. In some embodiments, the isolation material 132 is formed of and includes SiOₓ (e.g., SiO₂). The isolation material 132 may be substantially homogeneous, or the isolation material 132 may be heterogeneous.

Referring next to FIG. 3B, the second base structure 202 of the second microelectronic device structure 200 may be formed as a non-volatile memory array structure. The second base structure 202 may vertically underlie the second dielectric material 204 and may include an additional semiconductor substrate 208 and a non-volatile memory array region 210 at least partially vertically overlying the additional semiconductor substrate 208. Second conductive contact bars 205 may be positioned in the second dielectric material 204 and connect to conductive leads 209 that connect to microelectronic components in other materials of the second microelectronic device structure 200. The non-volatile memory array region 210 includes a stack structure 218; deep contact structures 226 and cell pillar structures 230 vertically extending through the stack structure 218; a source tier 212 vertically underlying the stack structure 218; digit line structures 236 (e.g., bit line structures, data line structures) vertically overlying the stack structure 218; insulative line structures 238 vertically overlying the digit line structures 236; digit line contact structures 240 vertically extending through the insulative line structures 238 to the digit line structures 236; and conductive routing structures 242 vertically overlying the digit line contact structures 240. The second microelectronic device structure 200 includes additional features (e.g., structures, materials, devices), as described in further detail below.

The additional semiconductor substrate 208 may comprise a semiconductor structure (e.g., a semiconductive wafer), or a base semiconductor material on a supporting structure. For example, the additional semiconductor substrate 208 may comprise a conventional silicon substrate (e.g., a conventional silicon wafer), or another bulk substrate comprising a semiconductive material. In some embodiments, the additional semiconductor substrate 208 comprises a silicon wafer. The additional semiconductor substrate 208 may include one or more materials, structures, and/or regions formed therein and/or thereon.

The source tier 212 may be vertically interposed between the additional semiconductor substrate 208 and the stack structure 218 overlying the additional semiconductor substrate 208. The source tier 212 may include at least one source structure 214 (e.g., a source plate), and at least one contact pad 216. The source structure 214 and the contact pad 216 may horizontally neighbor one another (e.g., in the X-direction, in the Y-direction) within the source tier 212. The source structure 214 may be electrically isolated from the contact pad 216 and may be positioned at substantially the same vertical position (e.g., in the Z-direction) as the contact pad 216. At least one insulative material may be interposed between the source structure 214, the contact pad 216, the additional semiconductor substrate 208, and the stack structure 218, as described in further detail below.

The source structure 214 and the contact pad 216 may each be formed of and include conductive material. A material composition of the source structure 214 may be substantially the same as a material composition of the contact pad 216. In some embodiments, the source structure 214 and the contact pad 216 are respectively formed of and include one or more of a metal, an alloy, and a conductive metal-containing material (e.g., a conductive metal nitride, a conductive metal silicide, a conductive metal carbide, a conductive metal oxide). As a non-limiting example, the source structure 214 and the contact pad 216 may be formed of and include W. In additional embodiments, the source structure 214 and the contact pad 216 are formed of and include conductively doped semiconductor material, such as a conductively doped form of one or more of a silicon material, such as monocrystalline silicon or polycrystalline silicon; a silicon-germanium material; a germanium material; a gallium arsenide material; a gallium nitride material; and an indium phosphide material. As a non-limiting example, the source structure 214 and the contact pad 216 may be formed of and include silicon (e.g., polycrystalline silicon) doped with at least one dopant (e.g., one or more of at least one N-type dopant, at least one P-type dopant, and at least another dopant).

The source structure 214 of the source tier 212 may be coupled to the cell pillar structures 230. In some embodiments, the source structure 214 directly physically contacts the cell pillar structures 230. In additional embodiments, contact structures may vertically intervene between the source structure 214 and the cell pillar structures 230. In addition, the source structure 214 may also be coupled to and/or may subsequently be coupled to additional structures (e.g., contact structures, routing structures, pad structures) present within the second microelectronic device structure 200, as described in further detail below.

The contact pad 216 of the source tier 212 may be coupled to additional conductive features (e.g., conductive contact structures, conductive pillars) within the stack structure 218. For example, as shown in FIG. 3B, the contact pad 216 may be coupled to one or more of the deep contact structures 226 vertically extending through the stack structure 218. In some embodiments, the contact pad 216 directly physically contacts at least one of the deep contact structures 226. In additional embodiments, additional contact structures may vertically intervene between the contact pad 216 and an individual deep contact structure 226, and may couple the contact pad 216 to the deep contact structure 226. In addition, the contact pad 216 may be coupled to additional structures (e.g., contact structures, routing structures, pad structures) present within the second microelectronic device structure 200, as described in further detail below.

Still referring to FIG. 3B, the stack structure 218 may be formed to vertically overlie the source tier 212, and may include a vertically alternating (e.g., in the Z-direction) sequence of conductive material 222 and insulative material 220 arranged in tiers 224. Each of the tiers 224 of the stack structure 218 may include the conductive material 222 vertically neighboring the insulative material 220. The stack structure 218 may be formed to include any desired number of the tiers 224, such as greater than or equal to sixteen (16) of the tiers 224, greater than or equal to thirty-two (32) of the tiers 224, greater than or equal to sixty-four (64) of the tiers 224, greater than or equal to one hundred and twenty-eight (128) of the tiers 224, or greater than or equal to two hundred and fifty-six (256) of the tiers 224.

The conductive material 222 of the tiers 224 of the stack structure 218 may be formed of and include one or more of at least one metal, at least one alloy, and at least one conductive metal-containing material (e.g., a conductive metal nitride, a conductive metal silicide, a conductive metal carbide, a conductive metal oxide). In some embodiments, the conductive material 222 is formed of and includes W. Optionally, one or more liner materials (e.g., insulative liner materials, conductive liner materials) may be formed around the conductive material 222. The liner materials may, for example, be formed of and include one or more of a metal (e.g., Ti, Ta), an alloy, a metal nitride (e.g., WN_{y}, TiN_{y}, TaN_{y}), and a metal oxide (e.g., AlOₓ). In some embodiments, the liner materials comprise at least one conductive material employed as a seed material for the formation of the conductive material 222. In some embodiments, the liner materials comprise TiN_{y} and AlOₓ. As a non-limiting example, AlOₓ may be formed directly adjacent to the insulative material 220, TiN, may be formed directly adjacent to the AlOₓ, and W may be formed directly adjacent to the TiN_{y}. For clarity and ease of understanding the description, the liner materials are not illustrated in FIG. 3B, but it will be understood that the liner materials may be disposed around the conductive material 222.

The insulative material 220 of the tiers 224 of the stack structure 218 may be formed of and include one or more of at least one dielectric oxide material, at least one dielectric nitride material, at least one dielectric oxynitride material, and at least one dielectric carboxynitride material. In some embodiments, the insulative material 220 is formed of and includes a dielectric oxide material, such as SiOₓ (e.g., SiO₂).

The cell pillar structures 230 may vertically extend through the tiers 224 of the stack structure 218. The cell pillar structures 230 may respectively be formed of and include a stack of materials. By way of non-limiting example, each of the cell pillar structures 230 may be formed to include a charge-blocking material, such as first dielectric oxide material (e.g., SiOₓ, such as SiO₂; AlOₓ, such as Al₂O₃); a charge-trapping material, such as a dielectric nitride material (e.g., SiN_{y}, such as Si₃N₄); a tunnel dielectric material, such as a second oxide dielectric material (e.g., SiOₓ, such as SiO₂); a channel material, such as a semiconductor material (e.g., silicon, such as polycrystalline Si); and a dielectric fill material (e.g., dielectric oxide, dielectric nitride, air). The charge-blocking material may be formed on or over, and may substantially cover, surfaces of the stack structure 218 defining boundaries (e.g., horizontal boundaries, lower vertical boundaries) of the cell pillar structures 230, such as surfaces of the conductive material 222 and the insulative material 220 of the tiers 224 of the stack structure 218. The charge-trapping material may be formed on or over, and may substantially cover, the inner surfaces of the charge-blocking material. The tunnel dielectric material may be formed on or over, and may substantially cover, inner surfaces of the charge-trapping material. The channel material may be formed on or over, and may substantially cover, the inner surfaces of the tunnel dielectric material. The dielectric fill material may be formed on or over, and may substantially cover, inner surfaces of the channel material.

With continued reference to FIG. 3B, intersections of the cell pillar structures 230 and the conductive material 222 of some of the tiers 224 of the stack structure 218 may define vertically extending strings of memory cells 232 coupled in series with one another within the stack structure 218. In some embodiments, the memory cells 232 formed at the intersections of the conductive material 222 and the cell pillar structures 230 within different tiers 224 of the stack structure 218 comprise so-called “MONOS” (metal-oxide-nitride-oxide-semiconductor) memory cells. In additional embodiments, the memory cells 232 comprise so-called “TANOS” (tantalum nitride-aluminum oxide-nitride-oxide-semiconductor) memory cells, or so-called “BETANOS” (band/barrier engineered TANOS) memory cells, each of which are subsets of MONOS memory cells. In further embodiments, memory cells 232 comprise so-called “floating gate” memory cells including floating gates (e.g., metallic floating gates) as charge storage structures. The floating gates may horizontally intervene between central structures of the cell pillar structures 230 and the conductive material 222 of the different tiers 224 of the stack structure 218.

As shown in FIG. 3B, the deep contact structures 226 may also vertically extend through the tiers 224 of the stack structure 218. The deep contact structures 226 may be configured and positioned to electrically connect one or more features (e.g., structures, material, devices) of the second base structure 202 vertically overlying the stack structure 218 with one or more additional features of the second base structure 202 vertically underlying the stack structure 218. The deep contact structures 226 may be formed of and include conductive material. In some embodiments, the deep contact structures 226 are formed of and include W. In additional embodiments, the deep contact structures 226 are formed of and include conductively doped polycrystalline silicon.

Insulative liner structures 228 may be formed to substantially continuously extend over and substantially cover side surfaces of the deep contact structures 226. The insulative liner structures 228 may be horizontally interposed between the deep contact structures 226 and the conductive material 222 (and the insulative material 220) of tiers 224 of the stack structure 218. The insulative liner structures 228 may be formed over and include insulative material. In some embodiments, the insulative liner structures 228 are formed of and include dielectric oxide material (e.g., SiOₓ, such as SiO₂).

The digit line structures 236 may be formed vertically over and in electrical communication with the cell pillar structures 230 (and, hence, the vertically extending strings of memory cells 232). The digit line structures 236 may exhibit horizontally elongated shapes extending in parallel in a first horizontal direction (e.g., the Y-direction). As used herein, the term “parallel” means substantially parallel. The digit line structures 236 may be formed of and include conductive material. In some embodiments, the digit line structures 236 are individually formed of and include W.

The insulative line structures 238 may be formed on or over the digit line structures 236. The insulative line structures 238 may serve as insulative cap structures (e.g., dielectric cap structures) for the digit line structures 236. The insulative line structures 238 may have horizontally elongated shapes extending in parallel in the first horizontal direction (e.g., the Y-direction). Horizontal dimensions, horizontal pathing, and horizontal spacing of the insulative line structures 238 may be substantially the same as the horizontal dimensions, horizontal pathing, and horizontal spacing of the digit line structures 236. The insulative line structures 238 may be formed of and include insulative material. In some embodiments, the insulative line structures 238 are individually formed of and include dielectric nitride material, such as SiN_{y} (e.g., Si₃N₄).

The digit line contact structures 240 may be formed to vertically extend through the insulative line structures 238 and may contact the digit line structures 236. For each digit line contact structure 240, a first portion thereof may vertically overlie one of the insulative line structures 238, and a second portion thereof may vertically extend through the insulative line structure 238 and contact (e.g., physically contact, electrically contact) one of the digit line structures 236. The individual digit line contact structures 240 may be at least partially (e.g., substantially) horizontally aligned in the X-direction with individual insulative line structures 238 (and, hence, individual digit line structures 236). For example, horizontal centerlines of the digit line contact structures 240 in the X-direction may be substantially aligned with horizontal centerlines of the insulative line structures 238 in the X-direction. In addition, the digit line contact structures 240 may be formed at desired locations in the Y-direction along the insulative line structures 238 (and, hence, the digit line structures 236). In some embodiments, at least some of the digit line contact structures 240 are provided at different positions in the Y-direction than one another. The digit line contact structures 240 may each individually be formed of and include conductive material. In some embodiments, the digit line contact structures 240 are individually formed of and include Cu. In additional embodiments, the digit line contact structures 240 are individually formed of and include W.

The conductive routing structures 242 may vertically overlie digit line contact structures 240. Some of the conductive routing structures 242 may be coupled to the cell pillar structures 230 thereunder and some others of the conductive routing structures 242 may be coupled to the deep contact structures 226 thereunder. The conductive routing structures 242 may respectively be formed of and include conductive material. In some embodiments, the conductive routing structures 242 are individually formed of and include one or more of W, Ru, Mo, and TiN_{y}.

Still referring to FIG. 3B, additional isolation material 244 may be formed to cover and surround portions of the additional semiconductor substrate 208, the source structure 214, the contact pad 216, stack structure 218 (including the conductive material 222 and the insulative material 220 thereof), the digit line structures 236, the insulative line structures 238, the digit line contact structures 240, and the conductive routing structures 242. In some embodiments, the additional isolation material 244 is formed such that an upper surface thereof is substantially coplanar with upper surfaces of uppermost ones of the conductive routing structures 242. Accordingly, the second dielectric material 204 may be formed on upper surfaces of the additional isolation material 244 and the uppermost ones of the conductive routing structures 242. In additional embodiments, the additional isolation material 244 is formed to substantially cover the upper surfaces of the uppermost ones of the conductive routing structures 242. Accordingly, the second dielectric material 204 may be formed only on an upper surface of the additional isolation material 244. The additional isolation material 244 may be formed of and include insulative material. In some embodiments, the additional isolation material 244 is formed of and includes SiOₓ (e.g., SiO₂). The additional isolation material 244 may be substantially homogeneous, or the additional isolation material 244 may be heterogeneous.

Referring next to FIG. 3C, the second base structure 202 of the second microelectronic device structure 200 may alternatively be formed as a volatile memory array structure. The second base structure 202 may vertically underlie the second dielectric material 204, and may include a further semiconductor substrate 248, and a volatile memory array region 246 at least partially vertically overlying the further semiconductor substrate 248. Conductive contact bars 205 may be positioned in the second dielectric material 204 and connect to conductive leads 209 that connect to microelectronic components in other materials of the second microelectronic device structure 200. The further semiconductor substrate 248 includes semiconductor material 250 and isolation structures 254 (e.g., shallow trench isolation (STI) structures) vertically extending into the semiconductor material 250. The isolation structures 254 may define boundaries of active regions 252 of the semiconductor material 250, as described in further detail below. The isolation structures 254 may include trenches (e.g., openings, vias, apertures) within the semiconductor material 250 of further semiconductor substrate 248 filled with insulative material. In some embodiments, the isolation structures 254 are respectively formed of and include SiOₓ (e.g., SiO₂).

The isolation structures 254 may include first isolation structures 254A and second isolation structures 254B. The first isolation structures 254A may have one or more different geometric configuration(s) (e.g., different dimension(s), different shape(s)) and different horizontal positioning relative to the second isolation structures 254B. At least some of the first isolation structures 254A may respectively have different horizontal dimension(s) than at least some of the second isolation structures 254B. At least some of the isolation structures 254 (e.g., at least some of the first isolation structures 254A and/or at least some of the second isolation structures 254B) vertically extend to and terminate at a different vertical position than some others of the isolation structures 254 (e.g., at least some others of the first isolation structures 254A and/or at least some others of the second isolation structures 254B). For example, some of the isolation structures 254 may be formed to be relatively vertically shallower than some other of the isolation structures 254.

Some of the isolation structures 254 (e.g., some of the first isolation structures 254A) may at least partially define boundaries of the active regions 252 of the semiconductor material 250 of the further semiconductor substrate 248. The active regions 252 of the semiconductor material 250 may individually vertically extend (e.g., project) from a relatively lower portion of the semiconductor material 250 that horizontally extends across and between the active regions 252. The active regions 252 may be considered pillar structures of the semiconductor material 250.

The active regions 252 of the semiconductor material 250 may individually exhibit an elongate (e.g., non-circular, non-square) horizontal cross-sectional shape at least partially defined by the horizontal cross-sectional shapes of the first isolation structures 254A horizontally adjacent thereto. The active regions 252 may individually include an upper surface, opposing horizontal ends, and opposing horizontal sides extending from and between the opposing ends. Intersections of the opposing horizontal ends of an individual active region 252 with the opposing horizontal sides of the active region 252 may define horizontal corners of the active region 252. As shown in FIG. 3C, the upper surfaces of the active regions 252 may be substantially coplanar with one another. In addition, an individual active region 252 may include a digit line contact region (e.g., bit line contact region) and storage node contact regions (e.g., cell contact regions). The storage node contact regions of the active region 252 may be located proximate the opposing horizontal ends of the active region 252, and the digit line contact region may be horizontally interposed between the storage node contact regions. The digit line contact region may be positioned at or proximate to a horizontal center of the active region 252. In some embodiments, the digit line contact region of an individual active region 252 is horizontally narrower than each of the storage node contact regions of the active region 252. The digit line contact region and the storage node contact regions of an individual active region 252 may be separated from one another by a pair of the first isolation structures 254A.

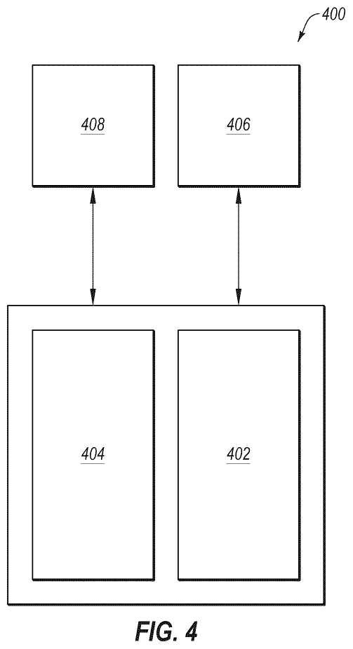

With continued reference to FIG. 3C, word line structures 256 may be at least partially embedded within the isolation structures 254 and may horizontally extend in parallel in the X-direction. In FIG. 3C, the illustrated word line structure 256 is depicted by way of dashed lines to represent that it is outside of (e.g., horizontally offset in the Y-direction from) the vertical plane depicted in FIG. 4. Side surfaces and a bottom surface of an individual word line structure 256 may be covered by insulative material of a respective one of the isolation structures 254. For example, portions of the isolation structure 254 may be horizontally interposed between the word line structure 256 and a respective active region 252 of the semiconductor material 250 of the further semiconductor substrate 248. The word line structures 256 may individually be formed of and include conductive material. In some embodiments, the word line structures 256 are individually formed of and include one or more of W, Ru, Mo, and TiN_{y}.

Within the volatile memory array region 246, the second base structure 202 further includes access devices 258. The access devices 258 may individually include a channel region comprising a portion of an active region 252 of the semiconductor material 250 of the further semiconductor substrate 248; a source region and a drain region respectively horizontally neighboring the channel region and individually comprising a conductively doped portion of the active region 252 of the semiconductor material 250 of the further semiconductor substrate 248; at least one gate structure comprising a portion of at least one of the word line structures 256; and a gate dielectric structure comprising a portion of the insulative material of the first isolation structure 254A interposed between the channel region thereof and the gate structure thereof.

Still referring to FIG. 3C, a first dielectric material 260 may be located on or over the further semiconductor substrate 248. The first dielectric material 260 may vertically overlie the access devices 258. The first dielectric material 260 may be formed of and include insulative material. In some embodiments, the first dielectric material 260 is formed of and includes dielectric oxide material (e.g., SiOₓ, such as SiO₂).

Digit line structures 262 may vertically overlie the first dielectric material 260 and may horizontally extend in parallel in the Y-direction. Tops (e.g., upper vertically boundaries) of the digit line structures 262 may be substantially coplanar with one another. The digit line structures 262 may individually be formed of and include conductive material. In some embodiments, the digit line structures 262 are individually formed of and include one or more of W, Ru, Mo, and TiN_{y}.

Digit line capping structures 264 may be formed on or over upper surfaces of the digit line structures 262, and digit line spacer structures 266 may be formed on or over side surfaces (e.g., sidewalls) of the digit line structures 262. The digit line capping structures 264 may at least partially (e.g., substantially) cover the upper surfaces of the digit line structures 262, and the digit line spacer structures 266 may at least partially (e.g., substantially) cover the side surfaces of the digit line structures 262. As shown in FIG. 3C, in some embodiments, upper boundaries of the digit line spacer structures 266 vertically overlie the upper surfaces of the digit line structures 262, and lower boundaries of the digit line spacer structures 266 vertically underlie lower surfaces of the digit line structures 262. The digit line capping structures 264 and the digit line spacer structures 266 may individually be formed of and include at least one insulative material. In some embodiments, the digit line capping structures 264 and the digit line spacer structures 266 are individually formed of and include one or more of dielectric oxide material (e.g., SiOₓ, such as SiO₂) and dielectric nitride material (e.g., SiN_{y}, such as Si₃N₄).

The volatile memory array region 246 may further include digit line contact structures (also referred to herein as “DIGITCON” structures) vertically overlying and in contact with the active regions 252 of the semiconductor material 250 of the further semiconductor substrate 248. The digit line contact structures may vertically extend through the first dielectric material 260 and into the active regions 252 of the semiconductor material 250 of the further semiconductor substrate 248. The digit line contact structures horizontally overlap (e.g., in the X-direction and the Y-direction) digit line contact sections of the active regions 252. The digit line contact structures may respectively vertically extend from a digit line contact section of an individual active region 252, through the first dielectric material 260, and to an individual digit line structure 262. An individual digit line contact structure may be horizontally interposed between two (2) of the word line structures 256 (and, hence, two (2) of the isolation structures 254) neighboring one another in the Y-direction, and may be horizontally interposed between two (2) storage node contact sections of an individual active region 252 in an additional horizontal direction angled relative to the Y-direction and the X-direction. An individual digit line contact structure may be coupled to one of the source/drain regions (e.g., the source region) of an individual access device 258. Within the horizontal area of an individual active region 252, an individual digit line contact structure may be coupled to two (2) (e.g., a pair) of the access devices 258 operatively associated with the active region 252. For example, the two (2) access devices 258 may share a source region within the active region 252 with one another, and the digit line contact structure may be coupled to the shared source region of the two (2) access devices 258. The digit line contact structures may individually be formed of and include conductive material.

The volatile memory array region 246 may further include storage node contact structures (also referred to herein as “CELLCON” structures) vertically overlying and in contact with the active regions 252 of the semiconductor material 250 of the further semiconductor substrate 248. The storage node contact structures may vertically extend through the first dielectric material 260 and into the active regions 252 of the semiconductor material 250 of the further semiconductor substrate 248. The storage node contact structures horizontally overlap (e.g., in the X-direction and the Y-direction) storage node contact sections of the active regions 252. The storage node contact structures may respectively vertically extend from a storage node contact section of an individual active region 252, through the first dielectric material 260, and to a redistribution material (RDM) structure 268 vertically overlying the digit line capping structures 264. An individual storage node contact structure may be horizontally interposed between two (2) of the word line structures 256 (and, hence, two (2) of the isolation structures 254) neighboring one another in the Y-direction and may horizontally neighbor the digit line contact section of an individual active region 252 in an additional horizontal direction angled relative to the Y-direction and the X-direction. An individual storage node contact structure may be coupled to one of the source/drain regions (e.g., the drain region) of an individual access device 258. Within the horizontal area of an individual active region 252, an individual storage node contact structure may be coupled to one (1) of two (2) (e.g., a pair) of access devices 258 operatively associated with the active region 252. For example, the two (2) of the access devices 258 have separate drain regions than one another within the active region 252, and the individual storage node contact structure may be coupled to the drain region of one (1) of the two (2) of the access devices 258. An individual active region 252 of the semiconductor material 250 may have two (2) storage node contact structures in contact therewith. The storage node contact structures may individually be formed of and include conductive material.

Still referring to FIG. 3C, the RDM structures 268 may be formed to vertically overlie the digit line capping structures 264. At least some of the RDM structures 268 may, for example, be employed to facilitate a horizontal arrangement (e.g., a hexagonal close packed arrangement) of storage node devices 272 that is different than a horizontal arrangement of the storage node contact structures, while electrically connecting the storage node contact structures (and, hence, the access devices 258) to the storage node devices 272. In addition, at least some other of the RDM structures 268 may vertically extend between and couple vertically neighboring conductive contact structures, as described in further detail below. The RDM structures 268 may individually be formed of and include conductive material. In some embodiments, the RDM structures 268 are individually formed of and include one or more of W, Ru, Mo, and TiN_{y}.

The storage node devices 272 (e.g., capacitors) may be formed on or over the RDM structures 268. The storage node devices 272 may be in electrical contact with the RDM structures 268, and, hence with the storage node contact structures, and the access devices 258. The storage node devices 272 may be coupled to the access devices 258 by way of the storage node contact structures and the RDM structures 268 to form memory cells 274 (e.g., volatile memory cells, such as DRAM cells). Each memory cell 274 may individually include one of the access devices 258, one of the storage node devices 272, one of the storage node contact structures, and one of the RDM structures 268. The storage node devices 272 may individually be formed and configured to store a charge representative of a programmable logic state of the memory cell 274 including the storage node device 272. In some embodiments, the storage node devices 272 are capacitors. During use and operation, a charged capacitor may represent a first logic state, such as a logic 1; and an uncharged capacitor may represent a second logic state, such as a logic 0. Each of the storage node devices 272 may, for example, be formed to include a first electrode (e.g., a bottom electrode), a second electrode (e.g., a top electrode), and a dielectric material between the first electrode and the second electrode.

At least one conductive routing tier including conductive routing structures 276 may be formed vertically over the memory cells 274. The conductive routing structures 276 may, for example, include one or more of pad structures and line structures. The conductive routing structures 276 may respectively be formed of and include conductive material. In some embodiments, the conductive routing structures 276 are individually formed of and include one or more of W, Ru, Mo, and TiN_{y}.

The first base structure 102 further includes first contact structures 270 and second contact structures 278 vertically overlying the first contact structures 270. As shown in FIG. 3C, some of the first contact structures 270 may vertically extend between and couple some of the RDM structures 268 and some of the word line structures 256. Some others of the first contact structures 270 may vertically extend between and couple some of the RDM structures 268 and some of the digit line structures 262. In addition, at least some of the second contact structures 278 may vertically extend between and couple some of the RDM structures 268 and some of the conductive routing structures 276 vertically overlying the memory cells 274. In FIG. 3C, the illustrated first contact structure 270 is depicted by way of dashed lines to represent that it is outside of (e.g., horizontally offset in the Y-direction from) the depicted vertical plane. The first contact structures 270 and the second contact structures 278 may respectively be formed of and include conductive material. In some embodiments, the first contact structures 270 and the second contact structures 278 are individually formed of and include one or more of W, Ru, Mo, and TiN_{y}.

A further isolation material 280 may be formed on or over portions of at least the further semiconductor substrate 248, the first dielectric material 260, the digit line capping structures 264, the RDM structures 268, the storage node devices 272, the memory cells 274, the first contact structures 270, the second contact structures 278, and the conductive routing structures 276. In some embodiments, the further isolation material 280 is formed such that an upper surface thereof is substantially coplanar with upper surfaces of uppermost ones of the conductive routing structures 276. Accordingly, the second dielectric material 204 may be formed on upper surfaces of the further isolation material 280 and the uppermost ones of the conductive routing structures 276. In additional embodiments, the further isolation material 280 is formed to substantially cover the upper surfaces of the uppermost ones of the conductive routing structures 276. Accordingly, the second dielectric material 204 may be formed only on an upper surface of the further isolation material 280. The further isolation material 280 may be formed of and include insulative material. In some embodiments, the further isolation material 280 is formed of and includes dielectric oxide material, such as SiOₓ (e.g., SiO₂).

Thus, in accordance with embodiments of the disclosure, a method of forming a microelectronic device includes forming a first microelectronic device structure comprising first conductive contact bars. The first conductive contact bars respectively include a first dimension in a first horizontal direction; and a second dimension in a second horizontal direction orthogonal to the first horizontal direction, the second dimension less than the first dimension. A second microelectronic structure is formed to include second conductive contact bars. The second conductive contact bars respectively include a first additional dimension in the first horizontal direction; and a second additional dimension in the second horizontal direction, the second additional dimension greater than the first additional dimension. The first microelectronic device structure is bonded to the second microelectronic structure such that the first conductive contact bars are bonded to the second conductive contact bars to form cruciform contact structures.

Furthermore, in accordance with embodiments of the disclosure, a microelectronic device includes a first microelectronic device structure, a second microelectronic device structure bonded to the first microelectronic device structure, and cruciform contact structures at a bonding interface of the first microelectronic device structure and the second microelectronic device structure. The cruciform contact structures respectively include a first conductive bar and a second conductive bar bonded to the first conductive bar. The first conductive bar has a first rectangular shape, a major horizontal dimension of the first conductive bar oriented in a first direction. The second conductive bar has a second rectangular shape, a major horizontal dimension of the second conductive bar oriented in a second direction orthogonal to the first direction.

Microelectronic device structures (e.g., the microelectronic device 300 (FIG. 1C)) in accordance with embodiments of the disclosure may be used in embodiments of electronic systems of the disclosure. For example, FIG. 4 is a block diagram illustrating an electronic system 400 according to embodiments of the disclosure. The electronic system 400 may comprise, for example, a computer or computer hardware component, a server or other networking hardware component, a cellular telephone, a digital camera, a personal digital assistant (PDA), portable media (e.g., music) material, a Wi-Fi or cellular-enabled tablet such as, for example, an iPAD® or SURFACE® tablet, an electronic book, a navigation device, etc. The electronic system 400 includes at least one memory device 402. The memory device 402 may comprise, for example, a microelectronic device structure (e.g., the microelectronic device 300 (FIG. 1C)) previously described herein. The electronic system 400 may further include at least one electronic signal processor device 404 (often referred to as a “microprocessor”). The electronic signal processor device 404 may, optionally, comprise a microelectronic device structure (e.g., the microelectronic device 300 (FIG. 1C)) previously described herein. While the memory device 402 and the electronic signal processor device 404 are depicted as two (2) separate devices in FIG. 4, in additional embodiments, a single (e.g., only one) memory/processor device having the functionalities of the memory device 402 and the electronic signal processor device 404 is included in the electronic system 400. In such embodiments, the memory/processor device may include a microelectronic device structure (e.g., the microelectronic device 300 (FIG. 1C)) previously described herein. The electronic system 400 may further include one or more input devices 406 for inputting information into the electronic system 400 by a user, such as, for example, a mouse or other pointing device, a keyboard, a touchpad, a button, or a control panel. The electronic system 400 may further include one or more output devices 408 for outputting information (e.g., visual or audio output) to a user such as, for example, a monitor, a display, a printer, an audio output jack, a speaker, etc. In some embodiments, the input device 406 and the output device 408 comprise a single touchscreen device that can be used both to input information to the electronic system 400 and to output visual information to a user. The input device 406 and the output device 408 may communicate electrically with one or more of the memory devices 402 and the electronic signal processor device 404.

Thus, in accordance with embodiments of the disclosure, an electronic system includes an input device, an output device, a processor device operably connected to the input device and the output device, and a memory device operably connected to the processor device. The memory device includes a control circuitry structure and a memory array structure vertically offset from and bonded to the control circuitry structure. The control circuitry structure includes control logic devices, and first conductive, rectangular bar structures vertically offset from and coupled to at least some of the control logic devices. The memory array structure includes memory cells, and second conductive, rectangular bar structures vertically offset from and coupled to at least some of the memory cells. The second conductive, rectangular bar structures are bonded to the first conductive, rectangular bar structures of the control circuitry structure.

The structures, devices, and methods of the disclosure advantageously facilitate one or more of improved microelectronic device structure performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

The embodiments of the disclosure described above and illustrated in the accompanying drawings do not limit the scope of the disclosure, which is encompassed by the scope of the appended claims and their legal equivalents. Any equivalent embodiments are within the scope of this disclosure. Indeed, various modifications of the disclosure, in addition to those shown and described herein, such as alternate useful combinations of the elements described, will become apparent to those skilled in the art from the description. Such modifications and embodiments also fall within the scope of the appended claims and equivalents.

What is claimed is:

1. A method of forming a microelectronic device, comprising:
forming a first microelectronic device structure comprising first conductive contact bars, the first conductive contact bars respectively including:
a first dimension in a first horizontal direction; and
a second dimension in a second horizontal direction orthogonal to the first horizontal direction, the second dimension less than the first dimension;
forming a second microelectronic device structure comprising second conductive contact bars, the second conductive contact bars respectively including:
a first additional dimension in the first horizontal direction; and
a second additional dimension in the second horizontal direction, the second additional dimension greater than the first additional dimension; and
bonding the first microelectronic device structure to the second microelectronic structure such that the first conductive contact bars are bonded to the second conductive contact bars to form cruciform contact structures.

2. The method of claim 1, further comprising:
forming the first conductive contact bars of the first microelectronic device structure to respectively have a rectangular horizontal cross-sectional shape; and
forming the second conductive contact bars of the second microelectronic device structure to respectively have an additional rectangular horizontal cross-sectional shape.

3. The method of claim 2, further comprising forming respective ones of the first conductive contact bars to have a horizontal area substantially equal to respective ones of the second conductive contact bars.

4. The method of claim 1, further comprising:
forming the first additional dimension of respective ones of the second conductive contact bars to be less than the first dimension of respective ones of the first conductive contact bars; and
forming the second additional dimension of the respective ones of the second conductive contact bars to be greater than the second dimension of the respective ones of the first conductive contact bars.

5. The method of claim 1, further comprising:
forming the first additional dimension of respective ones of the second conductive contact bars to be substantially equal to the second dimension of respective ones of the first conductive contact bars; and
forming the second additional dimension of the respective ones of the second conductive contact bars to be substantially equal to the first dimension of the respective ones of the first conductive contact bars.

6. The method of claim 1, wherein bonding the first microelectronic device structure to the second microelectronic structure comprises substantially aligning horizontal centers of respective ones of the first conductive contact bars with horizontal centers of respective ones of the first conductive contact bars to the cruciform contact structures.

7. The method of claim 1, wherein bonding the first microelectronic device structure to the second microelectronic structure comprises offsetting horizontal centers of respective ones of the first conductive contact bars from horizontal centers of respective ones of the first conductive contact bars to the cruciform contact structures.

8. The method of claim 1, wherein:
forming a first microelectronic device structure further comprises partially embedding the first conductive contact bars within a first insulative material, upper surfaces of the first conductive contact bars substantially coplanar with an upper surface of the first insulative material; and
forming a second microelectronic device structure further comprises partially embedding the second conductive contact bars within a second insulative material, upper surfaces of the second conductive contact bars substantially coplanar with an upper surface of the second insulative material.

9. The method of claim 8, wherein bonding the first microelectronic device structure to the second microelectronic structure comprises:
bonding the first dielectric material of the first microelectronic device structure to the second dielectric material of the second microelectronic structure through dielectric-to-dielectric bonding; and bonding the first conductive contact bars of the first microelectronic device structure to the second conductive contact bars of the second microelectronic structure through metal-to-metal bonding.

10. The method of claim 1, wherein:
forming a first microelectronic device structure further comprises forming the first conductive contact bars over one of an array of memory cells and control logic circuitry; and
forming a second microelectronic device structure further comprises forming the second conductive contact bars over one of an other array of memory cells and the control logic circuitry.

11. A microelectronic device, comprising:
a first microelectronic device structure;
a second microelectronic device structure bonded to the first microelectronic device structure; and
cruciform contact structures at a bonding interface of the first microelectronic device structure and the second microelectronic device structure, the cruciform contact structures respectively comprising:
a first conductive bar having a first rectangular shape, a major horizontal dimension of the first conductive bar oriented in a first direction; and
a second conductive bar bonded to the first conductive bar and having a second rectangular shape, a major horizontal dimension of the second conductive bar oriented in a second direction orthogonal to the first direction.

12. The microelectronic device of claim 11, wherein, for respective ones of the cruciform contact structures, a horizontal center of the first conductive bar is substantially aligned with a horizontal center of the second conductive bar.

13. The microelectronic device of claim 11, wherein, for respective ones of the cruciform contact structures, a horizontal center of the first conductive bar is offset in one or more in the first direction and the second direction than a horizontal center of the second conductive bar.

14. The microelectronic device of claim 11, wherein the second microelectronic device structure is bonded to the first microelectronic device structure through a combination of dielectric-to-dielectric bonds and metal-to-metal bonds.

15. The microelectronic device of claim 14, wherein the metal-to-metal bonds are between the first conductive bar and the second conductive bar of respective ones of the cruciform contact structures.

16. The microelectronic device of claim 11, wherein the first microelectronic device structure and second microelectronic device structure respectively comprise one of:
a control circuitry structure including control logic devices; and
a memory array structure including memory cells.

17. The microelectronic device of claim 16, wherein the memory cells of the memory array structure comprise volatile memory cells.

18. The microelectronic device of claim 16, wherein the memory cells of the memory array structure comprise non-volatile memory cells.

19. An electronic system, comprising:
an input device;
an output device;
a processor device operably connected to the input device and the output device;
a memory device operably connected to the processor device and comprising:
a control circuitry structure including:
control logic devices; and
first conductive, rectangular bar structures vertically offset from and coupled to at least some of the control logic devices; and
a memory array structure vertically offset from and bonded to the control circuitry structure, the memory array structure including:
memory cells; and
second conductive, rectangular bar structures vertically offset from and coupled to at least some of the memory cells, the second conductive, rectangular bar structures bonded to the first conductive, rectangular bar structures of the control circuitry structure.

20. The electronic system of claim 19, wherein major horizontal dimensions of the second conductive, rectangular bar structures of the horizontally extend perpendicular to major horizontal dimensions of the first conductive, rectangular bar structures.
